(19) United States
(12) Patent Application Publication
(10) Pub. No.: US 2026/0190744 A1
(43) Pub. Date: Jul. 2, 2026

(54) DISPLAY DEVICE

(71) Applicant: LG Display Co., Ltd., Seoul (KR)

(72) Inventors: TaeGyu LEE, Incheon (KR); Daesu KIM, Seoul (KR)

(73) Assignee: LG Display Co., Ltd., Seoul (KR)

(21) Appl. No.: 19/435,333

(22) Filed: Dec. 29, 2025

(30) Foreign Application Priority Data
Dec. 30, 2024 (KR) 10-2024-0200079

(51) Int. Cl. H10K 59/40; G06F 3/044; H10K 59/122; H10K 59/80

(52) U.S. Cl. CPC H10K 59/40; G06F 3/0446; H10K 59/122; H10K 59/8723; H10K 59/873; G06F 2203/04111

(57) ABSTRACT

The present disclosure relates to a display device. The display device includes a substrate on which a plurality of sub pixels is disposed, and a plurality of light emitting elements disposed in the plurality of sub pixels, each light emitting element including a first electrode, an organic layer, and a second electrode. A bank is disposed to cover an end of the first electrode, and a plurality of auxiliary electrodes is disposed on the bank. An encapsulation unit is disposed to cover the plurality of light emitting elements and the plurality of auxiliary electrodes. A touch sensing unit is disposed on the encapsulation unit and includes a plurality of touch electrodes and a plurality of bridge electrodes electrically connected to the plurality of touch electrodes. The plurality of auxiliary electrodes and the plurality of bridge electrodes are formed of the same material.

### CROSS-REFERENCE TO RELATED APPLICATIONS

This application claims the priority and benefit of Korean Patent Application No. 10-2024-0200079 filed on Dec. 30, 2024, in the Korean Intellectual Property Office, the disclosure of which is incorporated herein by reference in its entirety for all purpose as if fully set forth herein.

### BACKGROUND

### Technical Field

The present disclosure relates to a display device, and more particularly, to a display device capable of reducing a thickness of a laminated structure.

### Description of the Related Art

As it enters the information age, the field of display devices that visually display electrical information signals is rapidly developing, and research is being conducted to develop performances such as thinning, weight reduction, and low power consumption for various display devices.

Representative display devices include a liquid crystal display (LCD), a field emission display (FED), an electro-wetting display (EWD), and an organic light emitting display (OLED).

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device is excellent in implementation of colors, response speeds, viewing angles, and contrast ratios (CR).

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

The present disclosure describes a display device architecture that integrates OLED power distribution structures with touch sensing interconnects in a unified manner. In particular, auxiliary electrodes that supply low potential power to the second electrode of the light emitting elements and bridge electrodes that electrically connect adjacent touch electrodes are formed of the same material and by the same manufacturing process. By allowing these electrodes to serve dual electrical functions, the structure reduces the number of masks and process steps while maintaining uniform power delivery to the light emitting elements and stable signal transmission in the touch sensing unit.

The present disclosure describes an arrangement in which bridge electrodes are disposed on bank and spacer structures rather than on a separate touch interlayer. The spacers are shaped such that an upper portion is wider than a lower portion, causing the second electrode of the light emitting elements to be physically and electrically separated from the bridge electrodes in overlapping regions. In addition, the bridge electrodes and spacers may form closed curve or open curve shapes, which selectively control electrical isolation or continuity of the second electrode, thereby improving luminous efficiency while maintaining proper touch signal connectivity without additional insulating layers.

The present disclosure describes a reduced thickness display stack achieved by reusing existing layers for multiple functions. Organic insulating layers or color filter layers are used both to planarize the upper surface and to electrically insulate the touch electrodes from the bridge electrodes, eliminating the need for a dedicated touch interlayer insulating film. In some embodiments, a top color filter used in combination with a black bank and a low temperature black matrix allows omission of a polarization layer, thereby reducing overall thickness, improving flexibility, and simplifying manufacturing while maintaining optical performance and touch sensing reliability.

Various embodiments of the present disclosure provide a display device capable of reducing a thickness of a laminated structure.

Various embodiments of the present disclosure provide a display device capable of reducing a process cost and a process time of the display device.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate on which a plurality of sub pixels is disposed, a plurality of light emitting elements which are disposed in the plurality of sub pixels and includes a first electrode, an organic layer, and a second electrode, a bank which is disposed so as to cover an end of the first electrode, a plurality of auxiliary electrodes disposed on the bank, an encapsulation unit which is disposed so as to cover the plurality of light emitting elements and the plurality of auxiliary electrodes, and a touch sensing unit which is disposed on the encapsulation unit and includes a plurality of touch electrodes and a plurality of bridge electrodes which is electrically connected to the plurality of touch electrodes, the plurality of auxiliary electrodes and the plurality of bridge electrodes are formed of the same material.

According to another aspect of the present disclosure, a display device includes a substrate on which a plurality of sub pixels is disposed, a plurality of light emitting elements which are disposed in the plurality of sub pixels and includes a first electrode, an organic layer, and a second electrode, a bank which is disposed so as to cover an end of the first electrode, a plurality of auxiliary electrodes disposed on the bank, an encapsulation unit which is disposed so as to cover the plurality of light emitting elements and the plurality of auxiliary electrode, and a touch sensing unit which is disposed on the encapsulation unit and includes a plurality of touch electrodes and a plurality of bridge electrodes, the plurality of touch electrodes includes a plurality of first touch electrodes which extends in a first direction and is electrically connected to each other and a plurality of second touch electrodes which extends in a second direction intersecting the first direction, the bridge electrode is made of the same material as the plurality of auxiliary electrodes and electrically connects the plurality of second touch electrodes disposed adjacent to each other, and the plurality of bridge electrodes are disposed on the bank between the plurality of second touch electrodes.

According to an yet aspect of the present disclosure, a display device includes a substrate on which a plurality of sub pixels is disposed, a plurality of light emitting elements which are disposed in the plurality of sub pixels and includes a first electrode, an organic layer, and a second electrode, a bank which is disposed so as to cover an end of the first electrode, a plurality of auxiliary electrodes disposed on the bank and electrically connected to the second electrode.

Other detailed matters of the exemplary embodiments are included in the detailed description and the drawings.

In the display device of the present disclosure, a three-layer structure is disposed on a bank. The three-layer structure is configured to receive a low-potential voltage or to be used as a bridge electrode of a touch sensing unit according to its position. Accordingly, it is possible to reduce the process time and process cost when manufacturing the structure.

In the display device of the present disclosure, as the bridge electrode is disposed on the first spacer, a part of a layer included in the display device is integrated, so that the stacking thickness of the display device is reduced, thereby maximizing flexibility.

In the display device of the present disclosure, the polarization layer may be removed by disposing the color filter at the top, and the stacking thickness of the display device may be reduced.

The effects according to the present disclosure are not limited to the contents exemplified above, and more various effects are included in the present disclosure.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic perspective view of a display device according to an exemplary embodiment of the present disclosure.

FIG. 2 is a plan view schematically illustrating a touch panel TP structure applicable to a display device according to an exemplary embodiment of the present disclosure.

FIG. 3 is an enlarged schematic plan view of an area A of FIG. 2.

FIG. 4 is a cross-sectional view taken along the line IV-IV′ of FIG. 3.

FIG. 5 is a cross-sectional view taken along line V-V′ in FIG. 3.

FIGS. 6A to 6C are plan views illustrating shapes of a plurality of bridge electrodes according to an exemplary embodiment of the present disclosure.

FIGS. 7A to 7D are plan views illustrating shapes of a plurality of bridge electrodes according to another exemplary embodiment of the present disclosure.

FIG. 8 is a cross-sectional view of a display device according to still another exemplary embodiment of the present disclosure.

FIG. 9 is a cross-sectional view of a display device according to still another exemplary embodiment of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted or briefly given to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an exemplary embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms “first”, “second”, A, B, (a), (b), and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner.

As used herein, the term “intersect” is intended to be interpreted broadly and does not require that two elements physically contact or cross at a single point. The term includes, but is not limited to, configurations in which one element overlaps, traverses across, crosses over, is vertically aligned with, or extends over another element in a plan view or a cross-sectional view. The term may also encompass situations where elements are separated by one or more intervening layers, such as insulating films or dielectric structures. Accordingly, “intersect” should be understood to include relative positional arrangements that result in electrical, optical, or spatial alignment, even in the absence of direct physical contact.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the exemplary embodiments can be carried out independently of or in association with each other.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, exemplary embodiments of the present disclosure will be described in detail with reference to accompanying drawings.

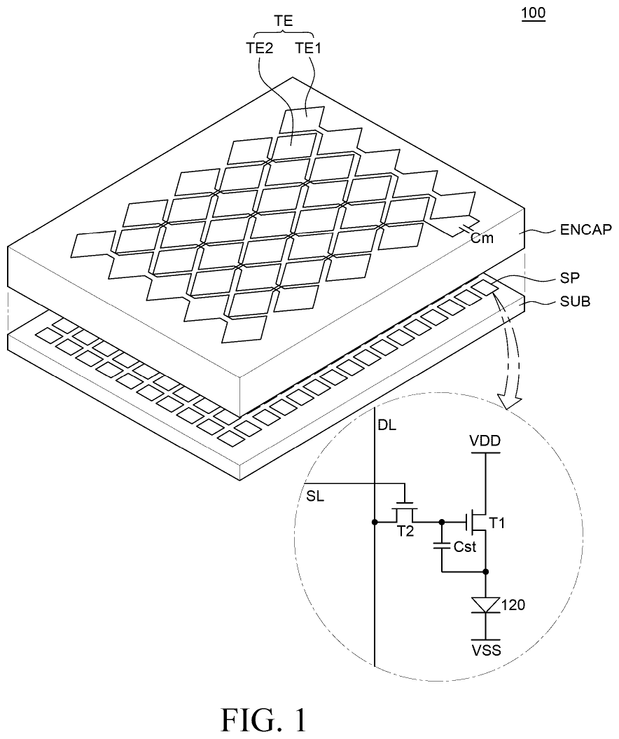

FIG. 1 is a schematic perspective view of a display device according to an exemplary embodiment of the present disclosure.

A display device 100 according to an exemplary embodiment of the present disclosure includes a plurality of sub pixels SP arranged in a matrix on an active area of a substrate SUB, an encapsulation unit ENCAP disposed on the plurality of sub pixels SP, and a plurality of touch electrodes TE disposed on the encapsulation unit ENCAP.

The substrate SUB is a component for supporting various components included in the display device 100 and may be formed of an insulating material. The substrate SUB may be formed of a transparent insulating material, for example, glass or resin. In addition, the substrate SUB may include polymer or plastic, or may be made of a material having flexibility.

For example, the substrate SUB may include a flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

Although not shown, a plurality of gate lines and a plurality of data lines are disposed to cross each other on the substrate SUB. A plurality of sub pixels SP is defined at intersections of a plurality of gate lines and a plurality of data lines. An area in which the plurality of sub pixels SP implementing an image is disposed may be expressed as an active area, and an area which is disposed outside the active area and in which the plurality of sub pixels SP is not disposed may be expressed as a non-active area.

The plurality of data lines and the plurality of gate lines may intersect one another. Each of the plurality of data lines may be configured to extend in a first direction. Each of the plurality of gate lines may be configured to extend in a second direction different from the first direction.

The active area is an area in which an image is displayed in the display device 100. In the active area AA, a plurality of sub pixels SP constituting a plurality of pixels and a pixel driving circuit for driving the plurality of sub pixels SP may be disposed. The plurality of sub-pixels SP is a minimum unit constituting the active area AA, and n sub-pixels SP may form one pixel. Transistors for driving a plurality of light emitting elements are disposed in each of the plurality of sub pixels SP so that the plurality of sub pixels SP may independently emit light. For example, the plurality of sub-pixels SP may include a red sub-pixel, a green sub-pixel, and a blue sub-pixel, but is not limited thereto and may include a red sub-pixel, a green sub-pixel, a blue sub-pixel, and a white sub-pixel. In another exemplary embodiment, the plurality of sub-pixels SP may include a cyan sub-pixel, a magenta sub-pixel and a yellow sub-pixel, but is not limited thereto.

The non-active area is an area in which no image is displayed and may be defined as an area extending from the active area AA. In the non-active area, a link line for transmitting a signal to the plurality of sub pixels SP of the active area and a pad electrode, or various ICs such as a gate driver IC and a data driver IC, and a COP or an FPCB on which driving circuits are disposed may be disposed. Further, a driving circuit referred to as a gate in panel (GIP) may be disposed in the non-active area.

In one or more aspects, at least one of the gate driver IC and the data driver IC may be disposed in the active area of a substrate SUB. For example, at least one of the gate driver IC and the data driver IC may be configured not to overlap with sub pixels SP, or configured to overlap with one or more, or all, of the sub pixels SP, or at least respective one or more portions of one or more sub pixels, without being limited thereto.

In the display device 100 according to the exemplary embodiment of the present disclosure, the display device 100 having a plurality of touch electrodes TE senses the presence of a touch and a touch position by sensing a change amount of mutual capacitance (Cm; touch sensor) caused by a user's touch through the plurality of touch electrodes TE during the touch period.

Each of the plurality of sub pixels SP disposed in the active area of the substrate includes a pixel driving circuit and a light emitting element connected to the pixel driving circuit.

As one example, the pixel driving circuit may include a plurality of transistors, a capacitor and a light emitting element. The pixel driving circuit may include a first transistor T1, a second transistor T2, a capacitor Cst, and a light emitting element 120, but is not limited thereto.

For example, the first transistor T1 may operate such that a driving current flows between the high potential power line VDD and the low potential power line VSS according to the data voltage stored in the capacitor Cst. In addition, the light emitting element 120 may operate to emit light according to the driving current formed by the first transistor T1. For example, the first transistor T1 may be referred to as a driving transistor. For example, when the first transistor T1 is turned on, the light emitting element 120may operate to emit light. Further, for example, the second transistor T2 may perform a switching operation so that a data signal supplied through the data line DL is stored in the capacitor Cst as a data voltage in response to a scan signal supplied through the scan line SL. For example, the second transistor T2 may be referred to as a switching transistor. For example, when the second transistor T2 is turned on in response to the scan signal supplied through the scan line SL, the data signal supplied through the data line DL is stored in the capacitor Cst.

The sub pixel illustrated in FIG. 1 is configured by a 2T(transistor)1C(capacitor) structure including a first transistor T1, a second transistor T2, a capacitor Cst, and a light emitting element 120, but is not limited thereto. When the compensation circuit 135 is added, the sub pixel may be configured in various forms, such as 3T1C, 4T2C, 5T2C, 6T1C, 6T2C, 7T1C, and 7T2C.

Since the light emitting element 120 in each sub-pixel SP is vulnerable to external moisture or oxygen, the encapsulation unit ENCAP for preventing external moisture or oxygen from penetrating into the light emitting element 120 may be disposed on the substrate SUB. The encapsulation unit ENCAP may be disposed to cover the light emitting elements 120.

The encapsulation unit ENCAP (e.g., an encapsulation layer) may include a plurality of encapsulating layers including at least one inorganic encapsulating layer, and at least one organic encapsulating layer, but is not limited thereto.

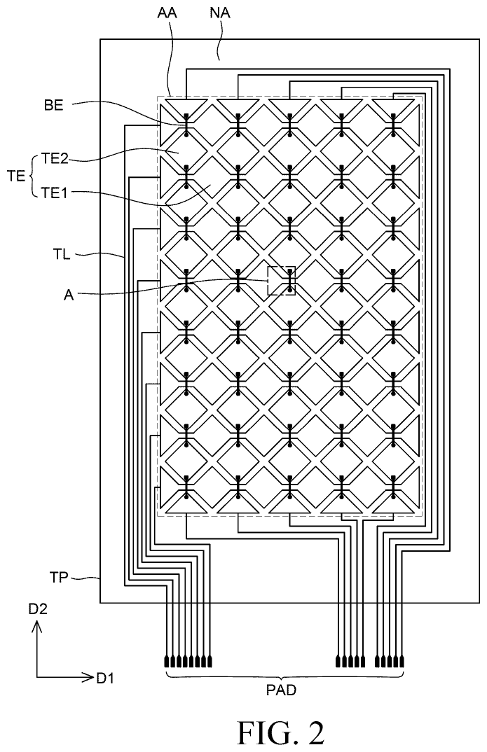

FIG. 2 is a plan view schematically illustrating a touch panel TP structure applicable to a display device according to an exemplary embodiment of the present disclosure.

The touch panel TP detects a user's touch input. Specifically, the touch panel TP may be referred to as a touch sensing unit.

The touch panel TP is manufactured separately from the display panel DP to be attached to the display panel DP in an add-on type or embedded in the display panel DP.

The touch panel TP may further include a touch driver configured to supply a touch driving signal to the touch panel TP and detect a touch sensing signal from the touch panel TP.

The touch driver determines whether the user touches and a touch position. For example, when the user touches a partial area of the touch panel TP, the touch driver detects a touch signal to determine whether the user touches the touch panel TP and a touch position.

Specifically, the touch driver may supply a touch driving signal to each touch panel TP. The touch driver may receive a touch sensing signal from the touch panel TP. The touch driver may sense a touch on the touch panel TP through the touch sensing signal.

As one example, the touch panel TP may include a plurality of touch electrodes. According to the mutual-capacitance sensing technique, a plurality of touch electrodes may be divided into driving touch electrodes and sensing touch electrodes. The touch driver can drive the driving touch electrodes and sense the sensing touch electrodes.

For example, the touch panel TP includes a plurality of first touch electrodes TE1, a plurality of second touch electrodes TE2, a plurality of bridge electrodes BE, a plurality of touch routing lines TL, and a plurality of touch pads PAD.

The plurality of first touch electrodes TE1 may be touch driving electrodes, and the plurality of second touch electrodes TE2 may be touch sensing electrodes. The plurality of first touch electrodes TE1 is connected in the first direction D1 to form a plurality of electrode rows, and the plurality of second touch electrodes TE2 extends in the second direction D2 intersecting the first direction D1 to be connected by the bridge electrode BE to form a plurality of electrode columns.

The plurality of first touch electrodes TE1 and the plurality of second touch electrodes TE2 may be disposed on the same layer. However, in an area where the plurality of first touch electrodes TE1 and the plurality of second touch electrodes TE2 intersect, the plurality of second touch electrodes TE2 may be disposed to be separated, and the plurality of separated second touch electrodes TE2 may be connected by the bridge electrode BE, but is not limited thereto. For example, the adjacent ones among the plurality of separated second touch electrodes TE2 may be connected by the bridge electrode BE. An organic insulating layer may be disposed between the plurality of bridge electrodes BE and the plurality of touch electrodes TE to insulate the plurality of touch electrodes TE and the bridge electrode BE.

In this case, the plurality of first touch electrodes TE1, the plurality of second touch electrodes TE2, and the plurality of bridge electrodes BE are disposed in an area corresponding to the active area AA of the substrate SUB.

The outer shapes of the plurality of first touch electrodes TE1 and the plurality of second touch electrodes TE2 may correspond to a specific shape. For example, as illustrated in FIG. 2, outer shapes of the plurality of first touch electrodes TE1 and the plurality of second touch electrodes TE2 may have a mesh pattern including a plurality of rhombic shapes. The plurality of first touch electrodes TE1 and the plurality of second touch electrodes TE2 may be formed of a metal including at least any one of titanium (Ti), aluminum (Al), molybdenum (Mo), Molytitanium (MoTi), copper (Cu), and tantalum (Ta), or may be formed of a transparent conductive material such as indium tin oxide (ITO), indium zinc oxide (IZO), but is not limited thereto. Light emitted from the display device 100 may pass through the plurality of first touch electrodes TE1 and the plurality of second touch electrodes TE2 made of a transparent conductive material and be emitted to the outside. However, the present disclosure is not limited thereto, and light emitted from the display device 100 may be emitted to the outside through a plurality of openings included in the plurality of first touch electrodes TE1 and the plurality of second touch electrodes TE2. For example, the plurality of first touch electrodes TE1 and the plurality of second touch electrodes TE2 may be made of a transparent conductive material, or the plurality of first touch electrodes TE1 and the plurality of second touch electrodes TE2 may include the plurality of openings, but is not limited thereto.

A plurality of touch routing lines TL and a plurality of touch pads PAD are disposed in an area corresponding to the non-active area NA in the touch panel TP, but is not limited thereto.

Each of the plurality of touch routing lines TL electrically connects each of the plurality of touch electrodes TE disposed in the active area AA to the touch pad PAD in the non-active area NA. As one example, the touch driving signal may be applied to plurality of first touch electrodes TE1 and the plurality of second touch electrodes TE2. For example, a touch driving signal may be applied to the plurality of first touch electrodes TE1 through the touch routing line TL connected to the plurality of first touch electrodes TE1 and a touch sensing signal may be transmitted to the plurality of second touch electrodes TE2 through the touch routing line TL connected to the plurality of second touch electrodes TE2.

The touch routing line TL may be made of a low-resistance metal material, or may be made of a transparent conductive material such as ITO or IZO, but is not limited thereto. For example, when the plurality of touch routing lines TL is made of a low-resistance metal material, the resistance is lowered and the RC delay may be lowered.

One end of the plurality of touch pads PAD is connected to the touch routing line TL, and the other end is electrically connected to an external circuit such as a touch driver to receive a touch signal from the external circuit or transmit a touch sensing signal to the external circuit.

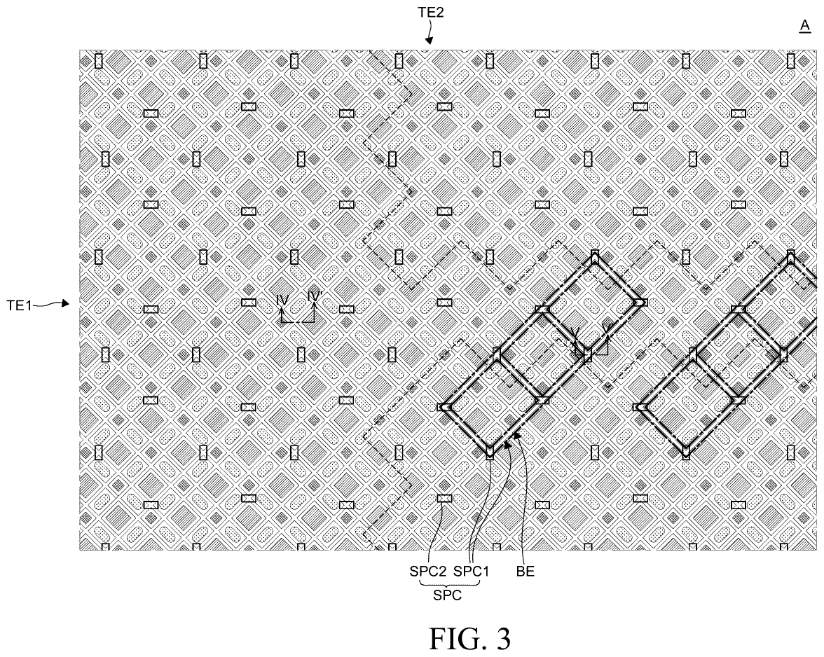

Hereinafter, an active area AA of the display device 100 will be described in more detail with reference to FIGS. 3 to 6C.

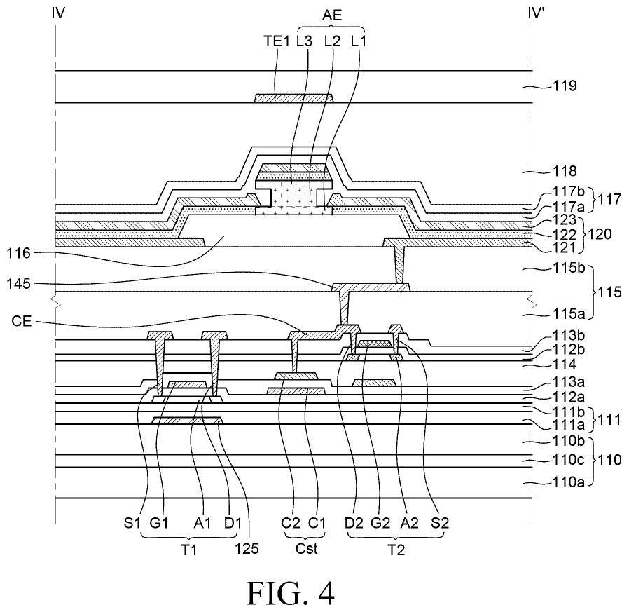

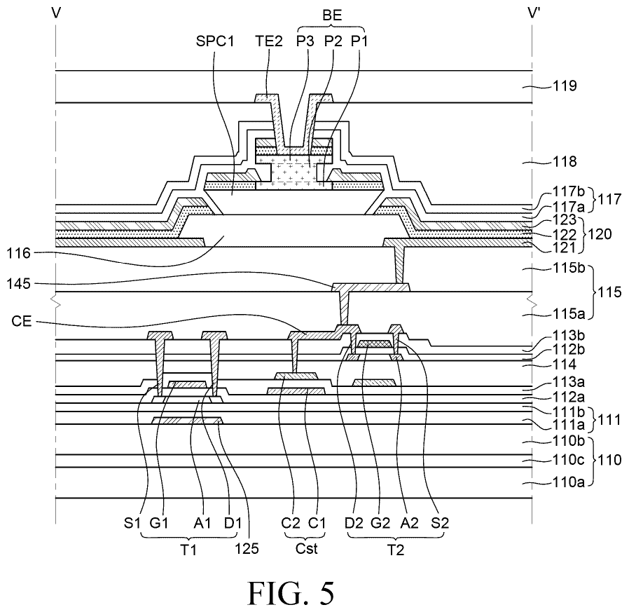

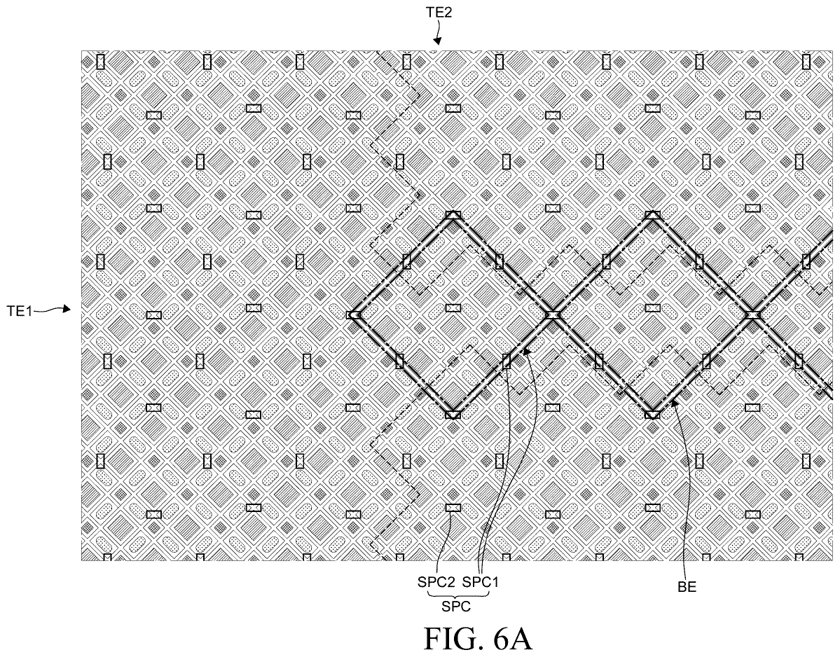

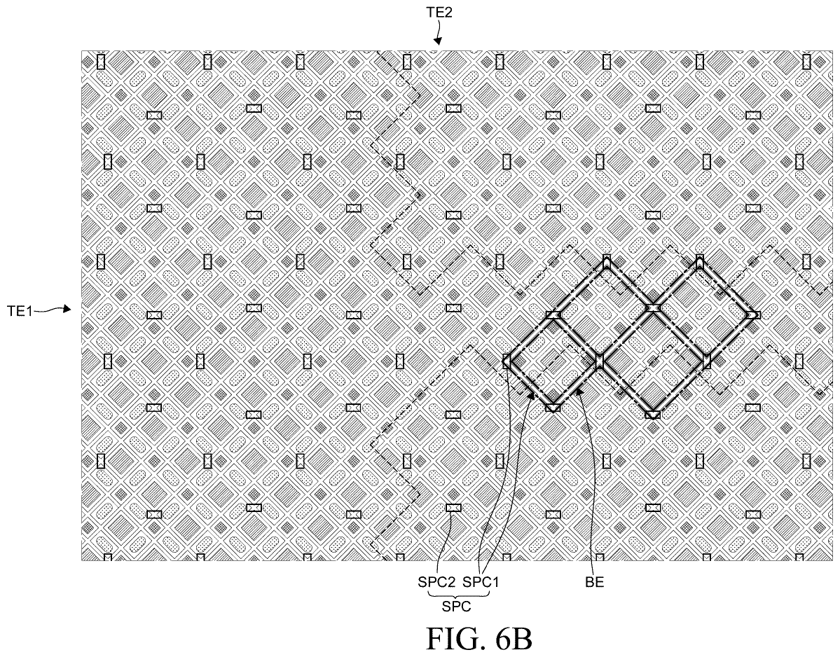

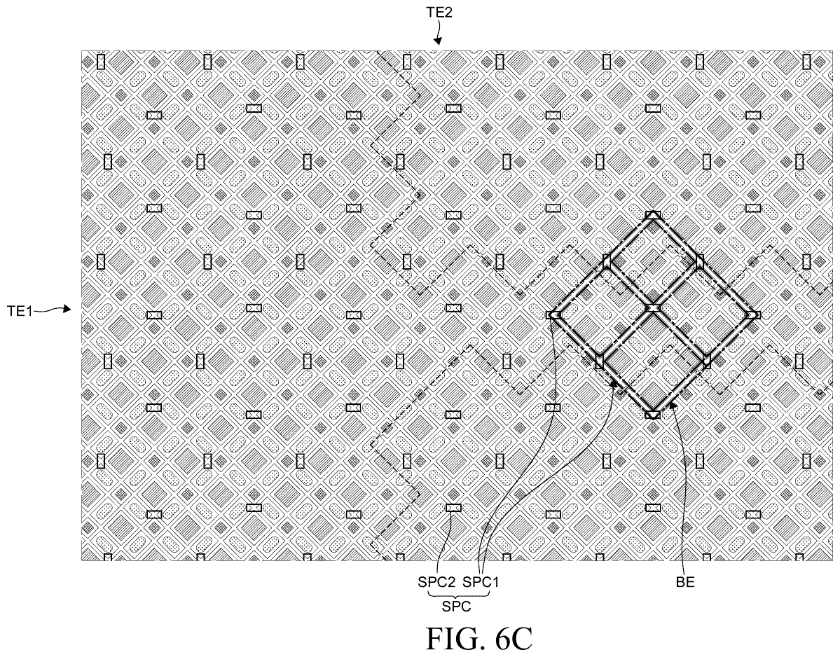

FIG. 3 is an enlarged schematic plan view of an area A of FIG. 2. FIG. 4 is a cross-sectional view taken along the line IV-IV′ of FIG. 3. FIG. 5 is a cross-sectional view taken along line V-V′ in FIG. 3. FIGS. 6A to 6C are plan views illustrating shapes of a plurality of bridge electrodes according to an exemplary embodiment of the present disclosure. In FIG. 3, for the convenience of description, among various components of the display device 100, only a plurality of sub pixels SP, a plurality of spacers SPC, a plurality of first touch electrodes TE1, a plurality of second touch electrodes TE2, and a plurality of bridge electrodes BE are illustrated.

FIG. 3 shows an enlarged area in which a plurality of first touch electrodes TE1 and a plurality of second touch electrodes TE2 intersect each other. The plurality of first touch electrodes TE1 and the plurality of second touch electrodes TE2 may be insulated from each other on the same layer. The plurality of first touch electrodes TE1 and the plurality of second touch electrodes TE2 may be divided based on a disconnected portion, for example, the dotted line of FIG. 3.

Referring to FIGS. 4 and 5, the substrate 110 is a component for supporting various components included in the display device 100 and may be formed of an insulating material. The substrate 110 may include a first substrate 110a, a second substrate 110b, and an insulating layer 110c. The insulating layer 110c may be disposed between the first substrate 110a and the second substrate 110b. As described above, the substrate 110 is configured by the first substrate 110a, the second substrate 110b, and the insulating layer 110c to suppress moisture permeation. For example, the first substrate 110a and the second substrate 110b may be polyimide (PI) substrates, and the insulating layer 110c may be formed of a single layer of silicon nitride (SiNx) or silicon oxide (SiOx) or a multi-layer thereof, but is not limited thereto.

A light shielding layer 125 may be disposed on the substrate 110. For example, the light shielding layer 125 may be disposed on a portion of the second substrate 110b of the substrate 110, but is not limited thereto.

The first buffer layer 111 may be disposed on the substrate 110 while covering the light shielding layer 125. Specifically, a multi-buffer layer 111a may be disposed on the substrate 110 while covering the light shielding layer 125, and an active buffer layer 111b may be disposed on the multi-buffer layer 111a. For example, the multi-buffer layer 111a may be disposed on the light shielding layer 125 and the portion of the substrate 110 exposed by the light shielding layer 125.

The multi-buffer layer 111a delays diffusion of moisture or oxygen permeating the substrate 110 and may include at least one of silicon nitride (SiNx) and silicon oxide (SiOx).

The active buffer layer 111b may protect the first active layer A1 of the first transistor T1 and block various types of defects introduced from the substrate 110. For example, the active buffer layer 111b may include at least one of a-Si, silicon nitride (SiNx), and silicon oxide (SiOx).

The first transistor T1 may be disposed on the first buffer layer 111. The first transistor T1 may include a first active layer A1, a first gate electrode G1, a first source electrode S1, and a first drain electrode D1. Here, depending on the design of the pixel circuit, the first source electrode S1 may be the first drain electrode, and the first drain electrode D1 may be the first source electrode.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

The first active layer A1 may be disposed on the first buffer layer 111 so as to overlap the light shielding layer 125. The first active layer A1 may include amorphous silicon or polycrystalline silicon. For example, the first active layer A1 may include low-temperature polysilicon (LTPS). For example, the polysilicon material has a high mobility (100 cm2/Vs or higher), low energy power consumption, and excellent reliability. Therefore, the polysilicon material may be applied to a gate driver for a driving element which drives transistors for a display element and/or a multiplexer (MUX), and may be applied as the first active layer A1 of a driving transistor in the display device 100 according to an exemplary embodiment of the present disclosure, but is not limited thereto. For example, it may be applied to the second active layer A2 of the switching transistor according to the characteristics of the display device 100. A polysilicon is formed by depositing an amorphous silicon (a-Si) material on the first buffer layer 111, performing a dehydrogenation process and a crystallization process, and the polysilicon is patterned to form the first active layer A1. Here, the first active layer A1 may include a first channel region in which a channel is formed when the first transistor T1 is driven, and a first source region and a first drain region on both sides of the first channel region. The first source region refers to a portion of the first active layer A1 connected to the first source electrode S1, and the first drain region refers to a portion of the first active layer A1 connected to the first drain electrode D1. For example, the first source region and the first drain region may be configured by ion-doping (impurity doping) of the first active layer A1. The first source region and the first drain region may be generated by doping ions into the polysilicon material, and the first channel region may mean a portion in which the ions are not doped, but the polysilicon material remains.

The first gate insulating layer 112a may be disposed on the first active layer A1. The first gate insulating layer 112a is an insulating layer for insulating the first active layer A1 and the first gate electrode G1 of the first transistor T1 from each other. The first gate insulating layer 112a may be configured by a single layer of silicon nitride (SiNx) or silicon oxide (SiOx) or a multi-layer thereof, but is not limited thereto.

The first gate electrode G1 of the first transistor T1 and the first capacitor electrode C1 of the storage capacitor Cst may be disposed on the first gate insulating layer 112a.

In this case, the first gate electrode G1 and the first capacitor electrode C1 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto. The first gate electrode G1 may be formed on the first gate insulating layer 112a so as to overlap the first channel region of the first active layer A1 of the first transistor T1.

The first capacitor electrode C1 may be omitted based on the driving characteristics of the display device 100 and the structure and type of the transistor. The first gate electrode G1 and the first capacitor electrode C1 may be formed of the same material and may be formed on the same layer, but is not limited thereto.

The first interlayer insulating layer 113a may be disposed on the first gate insulating layer 112a, the first gate electrode G1, and the first capacitor electrode C1. For example, the first interlayer insulating layer 113a may be disposed on the first gate electrode G1, and the first capacitor electrode C1 and a portion of the first gate insulating layer 112a exposed by the first gate electrode G1 and the first capacitor electrode C1. The first interlayer insulating layer 113a may be configured by a single layer of silicon nitride (SiNx) or silicon oxide (SiOx) or a multi-layer thereof.

The second capacitor electrode C2 of the storage capacitor Cst may be disposed on the first interlayer insulating layer 113a. The second capacitor electrode C2 may be formed by a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof. The second capacitor electrode C2 may be formed on the first interlayer insulating layer 113a so as to overlap the first capacitor electrode C1. Further, the second capacitor electrode C2 may be formed of the same material as the first capacitor electrode C1, but is not limited thereto. For example, the second capacitor electrode C2 may be formed of the same material as the first capacitor electrode C1 and the first gate electrode G1, but is not limited thereto. The second capacitor electrode C2 may be omitted based on the driving characteristics of the display device 100 and the structure and type of the transistor.

A second buffer layer 114 may be disposed on the first interlayer insulating layer 113a and the second capacitor electrode C2. The second buffer layer 114 may be configured by a single layer of silicon nitride (SiNx) or silicon oxide (SiOx) or a multi-layer thereof.

The second buffer layer 114 may be formed by a multi-layer, but is not limited thereto.

The second active layer A2 of the second transistor T2 may be disposed on the second buffer layer 114. Here, the second transistor T2 may include a second active layer A2, a second gate insulating layer 112b, a second gate electrode G2, a second source electrode S2, and a second drain electrode D2. Here, depending on the design of the pixel circuit, the second source electrode S2 may be a drain electrode, and the second drain electrode D2 may be a source electrode.

Further, the second active layer A2 may include a second channel region in which a channel is formed when the second transistor T2 is driven, and a second source region and a second drain region on both sides of the second channel region. The second source region may refer to a portion of the second active layer A2 connected to the second source electrode S2, and the second drain region may refer to a portion of the second active layer A2 connected to the second drain electrode D2.

The second active layer A2 may be formed of an oxide semiconductor. Since the oxide semiconductor material has a larger band gap than the silicon material, electrons cannot cross the band gap in an off state, and accordingly, the off-current is low. Therefore, the transistor including the active layer made of the oxide semiconductor may be suitable for a switching transistor that maintains the short on-time and the long off-time, but is not limited thereto. Depending on the characteristics of the display device 100, it may be applied as a driving transistor. Since the off-current is low, the size of the auxiliary capacity may be reduced, and thus, it is suitable for a high-resolution display element. For example, the second active layer A2 may be made of a metal oxide and for example, may be made of various metal oxides such as indium-gallium-zinc-oxide (IGZO). Here, it is assumed and described that the second active layer A2 of the second transistor T2 is formed of IGZO among various metal oxides, but it is not limited thereto and may be formed of other metal oxides such as indium-zinc-oxide (IZO), indium-gallium-tin-oxide (IGTO), or indium-gallium-oxide (IGO), rather than IGZO.

The second active layer A2 may be formed by depositing a metal oxide on the second buffer layer 114, performing a heat treatment for stabilization, and then patterning the metal oxide, but is not limited thereto.

The second gate insulating layer 112b may be disposed on the entire substrate 110 including the second active layer A2. For example, the second gate insulating layer 112b may be configured by a single layer of silicon nitride (SiNx) or silicon oxide (SiOx) or a multi-layer thereof.

The second gate electrode G2 may be disposed on the second gate insulating layer 112b. For example, the second gate electrode G2 may be disposed on a portion of the second gate insulating layer 112b.

The second gate electrode G2 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto.

The second interlayer insulating layer 113b may be disposed on the second gate insulating layer 112b and the second gate electrode G2. For example, the second interlayer insulating layer 113b may be disposed on the second gate electrode G2 and a portion of the second gate insulating layer 112b exposed by the second gate electrode G2.

The second interlayer insulating layer 113b may be configured by a single layer of silicon nitride (SiNx) or silicon oxide (SiOx) or a multi-layer thereof, but is not limited thereto.

The first connection electrode CE, the first source electrode S1 and the first drain electrode D1 of the first transistor T1, and the second source electrode S2 and the second drain electrode D2 of the second transistor T2 may be disposed on the second interlayer insulating layer 113b.

The first connection electrode CE may be electrically connected to the second drain electrode D2 of the second transistor T2. Further, the first connection electrode CE may be electrically connected to the second capacitor electrode C2 of the storage capacitor Cst. For example, the first connection electrode CE may serve to electrically connect the second capacitor electrode C2 of the storage capacitor Cst and the second drain electrode D2 of the second transistor T2.

For example, the first connection electrode CE may be electrically connected to the second drain electrode D2 of the second transistor T2 through the hole passing through the second gate insulating layer 112b and the second interlayer insulating layer 113b. The first connection electrode CE may be electrically connected to the second capacitor electrode C2 of the storage capacitor Cst through the hole passing through the second gate insulating layer 112b, the second interlayer insulating layer 113b and the second buffer layer 114, but is not limited thereto.

Here, the first source electrode S1 and the first drain electrode D1 of the first transistor T1 may be connected to the first active layer A1 of the first transistor T1.

The second source electrode S2 and the second drain electrode D2 of the second transistor T2 may be connected to the second active layer A2.

The first connection electrode CE, the first source electrode S1 and the first drain electrode D1 of the first transistor T1, and the second source electrode S2 and the second drain electrode D2 of the second transistor T2 may be formed of the same material by the same process, but is not limited thereto. For example, the first connection electrode CE, the first source electrode S1 and the first drain electrode D1 of the first transistor T1, and the second source electrode S2 and the second drain electrode D2 of the second transistor T2 may be formed on a same layer.

For example, the first connection electrode CE, the first source electrode S1 and the first drain electrode D1 of the first transistor T1, and the second source electrode S2 and the second drain electrode D2 of the second transistor T2 may be formed by a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof. For example, the first connection electrode CE, the first source electrode S1 and the first drain electrode D1 of the first transistor T1, and the second source electrode S2 and the second drain electrode D2 of the second transistor T2 may have a three-layer structure of titanium (Ti)/aluminum (Al)/titanium (Ti), but are not limited thereto.

The first connection electrode CE may be integrally connected to the second drain electrode D2 of the second transistor T2, but is not limited thereto.

The first planarization layer 115a may be disposed above the first connection electrode CE, the first source electrode S1 and the first drain electrode D1 of the first transistor T1, the second source electrode S2 and the second drain electrode D2 of the second transistor T2, and the second interlayer insulating layer 113b.

The first planarization layer 115a may be an organic layer for planarizing and protecting upper portions of the first transistor T1 and the second transistor T2. For example, the first planarization layer 115a may be formed of an organic material such as acryl resin, epoxy resin, phenolic resin, polyamide resin, or polyimide resin, but is not limited thereto.

The second connection electrode 145 may be disposed on the first planarization layer 115a. The second connection electrode 145 may be connected to the second drain electrode D2 of the second transistor T2. The second connection electrode 145 may serve to electrically connect the second transistor T2 and the first electrode 121. For example, the second connection electrode 145 may serve to electrically connect the second drain electrode D2 of the second transistor T2 and the first electrode 121. Further, the second connection electrode 145 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof. The second connection electrode 145 may be formed of the same material as the second source electrode S2 and the second drain electrode D2 of the second transistor T2, but is not limited thereto.

The second planarization layer 115b may be disposed above the second connection electrode 145 and the first planarization layer 115a. For example, the second planarization layer 115b may be disposed above the second connection electrode 145 and a portion of the first planarization layer 115a exposed by the second connection electrode 145. For example, the second planarization layer 115b may be formed of an organic material such as acryl resin, epoxy resin, phenolic resin, polyamide resin, or polyimide resin.

The light emitting element 120 including the first electrode 121, the light emitting layer 122, and the second electrode 123 may be disposed on the second planarization layer 115b. The light emitting layer 122 may be disposed between the first electrode 121 and the second electrode 123.

The first electrode 121 may be disposed on the second planarization layer 115b. In this case, the first electrode 121 may be electrically connected to the second connection electrode 145. The first electrode 121 may be formed of a metallic material.

When the display device 100 is a top emission type in which light emitted from the light emitting element 120 is emitted above the substrate SUB on which the light emitting element 120 is disposed, the first electrode 121 may include a transparent conductive layer and a reflective layer on the transparent conductive layer. The transparent conductive layer may be made of a transparent conductive oxide such as ITO or IZO, and the reflective layer may be made of, for example, silver (Ag), aluminum (Al), gold (Au), molybdenum (Mo), tungsten (W), chromium (Cr), or an alloy thereof.

The bank 116 may be disposed while covering an end of the first electrode 121. A portion of the bank 116 corresponding to the emission area of the sub-pixel may be opened. A part of the first electrode 121 may be exposed through the open part of the bank 116 (hereinafter, referred to as an open area). In this case, the bank 116 may be made of an inorganic insulating material, such as silicon nitride (SiNx) or silicon oxide (SiOx), or an organic insulating material, such as benzocyclobutene-based resin, acrylic-based resin, or imide-based resin, but is not limited thereto. For example, the bank 116 may contain carbon black, but is not limited thereto. The bank 116 may also be made of a transparent insulating material.

Referring to FIG. 4, a plurality of auxiliary electrodes AE may be disposed on the bank 116.

In the active area AA, the plurality of auxiliary electrodes AE may be electrically connected to the plurality of low potential power lines VSS.

The plurality of auxiliary electrodes AE may include a first layer L1, a second layer L2 on the first layer L1, and a third layer L3 on the second layer L2. In this case, a width of the second layer L2 may be smaller than a width of the first layer L1 and a width of the third layer L3. For example, a thickness of the second layer L2 may be greater than a thickness of the first layer L1 and a width of the third layer L3. For example, each of the first layer L1, the second layer L2, and the third layer L3 may include any one of molybdenum (Mo), copper (Cu), titanium (Ti), aluminum (Al), chromium (Cr), gold (Au), nickel (Ni), and neodymium (Nd), or an alloy thereof, but is not limited thereto. For example, the plurality of auxiliary electrodes AE may have a three-layer structure of titanium (Ti)/aluminum (Al)/titanium (Ti) in which the first layer L1 is titanium (Ti), the second layer L2 is aluminum, and the third layer L3 is titanium (Ti), but is not limited thereto.

The light emitting layer 122 may be disposed in the open area of the bank 116 and in the vicinity of the open area of the bank. Accordingly, the light emitting layer 122 may be disposed to cover the first electrode 121 and the plurality of auxiliary electrodes AE exposed through the open area of the bank 116. The light emitting layer 122 may include a plurality of organic layers.

The second electrode 123 may be disposed on the light emitting layer 122. The second electrode 123 may be electrically connected to side surfaces of the plurality of auxiliary electrodes AE on the bank 116 to apply a low potential power voltage VSS. Accordingly, low potential power is evenly applied to the plurality of light emitting elements 120 in the active area AA to prevent an IR drop. For example, the plurality of auxiliary electrodes AE may be electrically connected to the second electrode 123.

The light emitting element 120 may be formed by the first electrode 121, the light emitting layer 122, and the second electrode 123. The light emitting layer 122 may be disposed between the first electrode 121 and the second electrode 123. For example, the light emitting layer 122 may include one or more of a hole injection layer (HIL), a hole transmitting layer (HTL), an electron transmitting layer (ETL) and an electron injection layer (EIL), but the present disclosure is not limited thereto.

The encapsulation unit 117 may be positioned on the light emitting element 120.

The encapsulation unit 117 may have a single-layered structure or a multi-layered structure. For example, the encapsulation unit 117 may include a first encapsulation layer 117a and a second encapsulation layer 117b disposed on the first encapsulation layer 117a.

In this case, the first encapsulation layer 117a and the second encapsulation layer 117b may be configured by inorganic layers, but is not limited thereto.

The first encapsulation layer 117a may be disposed to cover an upper surface of the second electrode 123 and disposed to be most adjacent to the light emitting element 120. The first encapsulation layer 117a may be formed of an inorganic insulating material on which low-temperature deposition may be performed. For example, the first encapsulation layer 117a may be made of silicon nitride (SiNx), silicon oxide (SiOx), silicon oxynitride (SiON), or aluminum oxide (Al2O3), but is not limited thereto.

The second encapsulation layer 117b may be formed above the substrate 110 on which the first encapsulation layer 117a is formed so as to cover a upper surface and a side surface of the first encapsulation layer 117a. In this case, the second encapsulation layer 117b may minimize or block the permeation of external moisture or oxygen into the first encapsulation layer 117a. For example, the second encapsulation layer 117b may be made of an inorganic insulating material such as silicon nitride (SiNx), silicon oxide (SiOx), silicon oxynitride (SiON), or aluminum oxide (Al2O3), but is not limited thereto.

The organic insulating layer 118 may be disposed on the encapsulation unit 117. The organic insulating layer 118 may protect the components thereunder and planarize the upper portion. For example, the organic insulating layer 118 may include an organic material such as acryl resin, epoxy resin, phenolic resin, polyamide resin, and polyimide resin, but is not limited thereto.

A touch sensing unit including a plurality of touch electrodes TE and a plurality of bridge electrodes BE may be disposed on the organic insulating layer 118. For example, the plurality of bridge electrodes BE may be electrically connected to the plurality of touch electrodes TE.

The plurality of touch electrodes TE may include a plurality of first touch electrodes TE1 extending in a first direction and electrically connected to each other, and a plurality of second touch electrodes TE2 extending in a second direction intersecting the first direction.

Referring to FIG. 3 together, the plurality of first touch electrodes TE1 and the plurality of second touch electrodes TE2 may be insulated from each other on the same layer.

Specifically, the plurality of first touch electrodes TE1 and the plurality of second touch electrodes TE2 may be disposed on the same layer. However, in an area where the plurality of first touch electrodes TE1 and the plurality of second touch electrodes TE2 intersect, the plurality of second touch electrodes TE2 may be disposed to be separated, and the plurality of separated second touch electrodes TE2 may be connected by the bridge electrode BE. An organic insulating layer 118 is disposed between the plurality of bridge electrodes BE and the plurality of touch electrodes TE to insulate the plurality of touch electrodes TE and the bridge electrode BE.

For example, when the plurality of touch electrodes TE and the bridge electrode BE are insulated by the organic insulating layer 118, the occurrence of unnecessary noise is reduced as the conductivity is lowered so that the touch performance may be improved.

Referring to FIGS. 4 and 5, the bridge electrode BE may be formed of the same material as the plurality of auxiliary electrodes AE. For example, the bridge electrode BE may include a first layer P1, a second layer P2 on the first layer P1, and a third layer P3 on the second layer P2. In this case, a width of the second layer P2 may be smaller than a width of the first layer P1 and a width of the third layer P3. For example, each of the first layer P1, the second layer P2, and the third layer P3 may include any one of molybdenum (Mo), copper (Cu), titanium (Ti), aluminum (Al), chromium (Cr), gold (Au), nickel (Ni), and neodymium (Nd), or an alloy thereof, but is not limited thereto. For example, the bridge electrode BE may have a three-layer structure of titanium (Ti)/aluminum (Al)/titanium (Ti) in which the first layer P1 is titanium (Ti), the second layer P2 is aluminum, and the third layer P3 is titanium (Ti).

Referring to FIGS. 3, 5, 6A, and 6C together, a plurality of spacers SPC may be disposed between the plurality of sub pixels SP.

For example, the plurality of spacers SPC may be disposed on the bank. For example, the plurality of spacers SPC may include a plurality of first spacers SPC1 disposed to overlap an area where the plurality of first touch electrodes TE1 and the plurality of second touch electrodes TE2 intersect and a plurality of second spacers SPC2 spaced apart from the plurality of first spacers SPC1.

Referring to FIG. 5, a plurality of first spacers SPC1 may be disposed on the bank 116 in an area overlapping the bridge electrode BE.

The plurality of first spacers SPC1 may have a shape in which a width of an upper surface is wider than a width of a lower surface. The connection of the second electrode 123 may be disconnected from the side surfaces of the plurality of first spacers SPC1 due to the shapes of the plurality of first spacers SPC1. Accordingly, in the area overlapping the plurality of first spacers SPC1, the second electrode 123 may be electrically disconnected from the bridge electrode BE.

In an area overlapping the plurality of first spacers SPC1, the bridge electrode BE may be electrically connected to the plurality of second touch electrodes TE2 to transmit a touch signal.

Referring to FIGS. 3, 6A to 6C, a plurality of first spacers SPC1 may be disposed to connect a plurality of adjacent second touch electrodes TE2. Further, the plurality of adjacent first spacers SPC1 may be connected to each other to have a closed curve shape. In this case, the plurality of bridge electrodes BE may have the same shape as the plurality of first spacers SPC1 on a plane. Accordingly, the area of the plurality of bridge electrodes BE is increased, so that a resistance that may be used as the bridge electrode BE of the display device 100 may be obtained.

The shapes of the plurality of first spacers SPC1 and the plurality of bridge electrodes BE may not be limited as long as they form a closed curve by connecting the plurality of second touch electrodes TE2.

The protective layer 119 may be disposed to cover the touch sensing unit. The protective layer 119 may be formed of an organic insulating layer. The protective layer 119 may protect the touch sensing unit and planarize an upper portion thereof. Further, the step at the upper layer of the display device 100 is prevented by the protective layer 119 to improve the visibility of the display device 100. For example, the protective layer 119 may include an organic material such as acryl resin, epoxy resin, phenolic resin, polyamide resin, and polyimide resin.

In general, in the case of a display device including an encapsulation unit covering a transistor and a light emitting element and a touch sensing unit on the encapsulation unit, as various layers are stacked, a stacking thickness of the display device increases, thereby reducing flexibility. In addition, in order to improve the efficiency and power consumption of the display device, when the low potential power line and the second electrode are electrically connected in the active area, there is a problem in that a mask process according to the addition of the structure is added.

Accordingly, in the display device 100 according to the exemplary embodiment of the present disclosure, the plurality of auxiliary electrodes AE and the plurality of bridge electrodes BE are formed by the same process and the same material to reduce the mask and reduce the process time and process cost.

Further, in the display device 100 according to the exemplary embodiment of the present disclosure, as the plurality of bridge electrodes BE is disposed on the first spacer SPC1, a part of a layer included in the display device may be integrated. For example, the organic insulating layer 118 may planarize the lower portion instead of the generally used organic encapsulation layer. Further, the organic insulating layer 118 serves as an insulating layer between the bridge electrode BE and the plurality of touch electrodes TE to exclude the touch interlayer insulating layer. Accordingly, in the display device 100 according to the exemplary embodiment of the present disclosure, the stacking thickness is reduced to maximize flexibility.

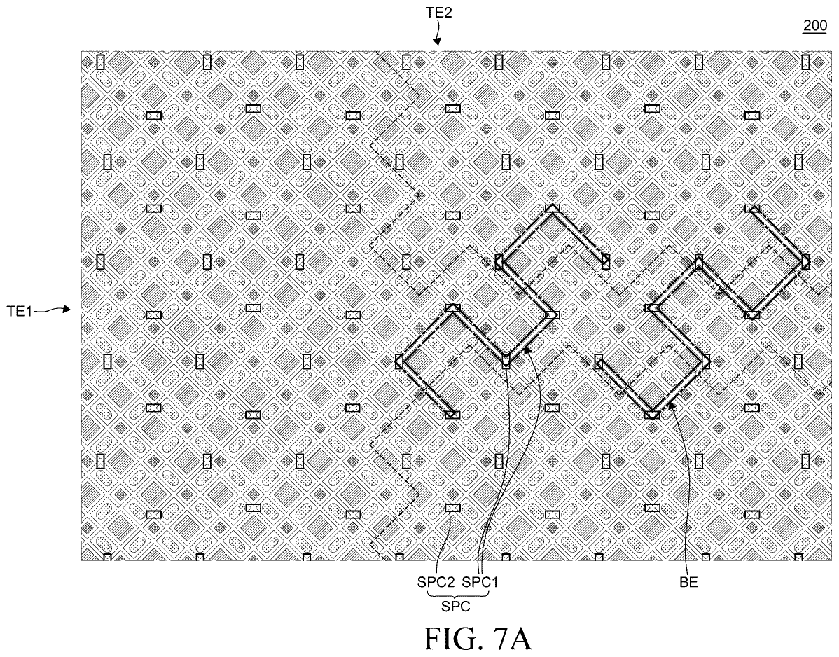

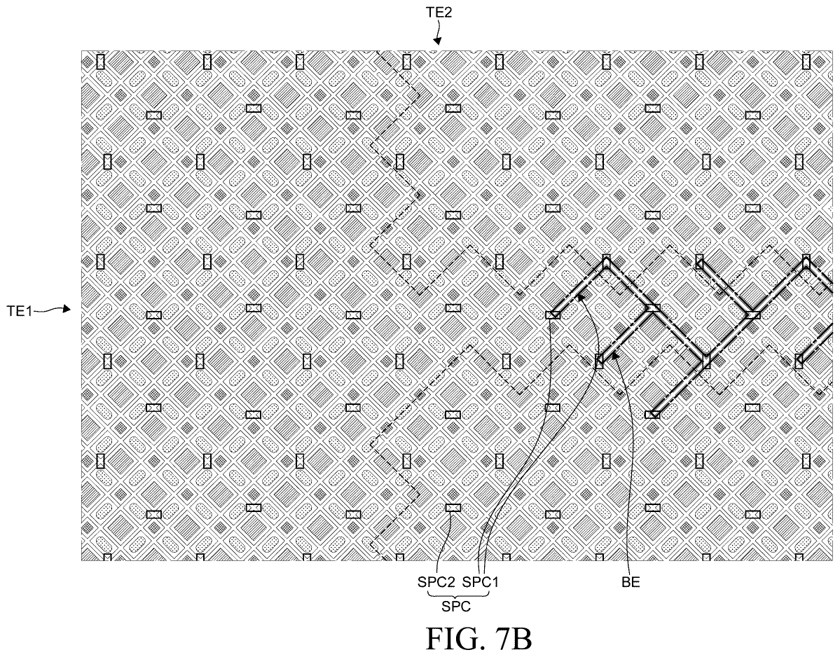

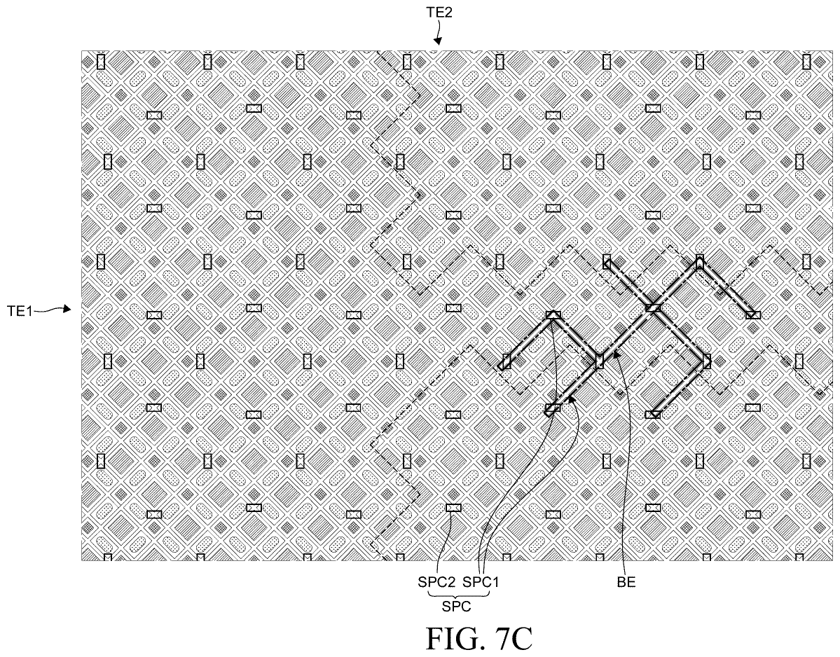

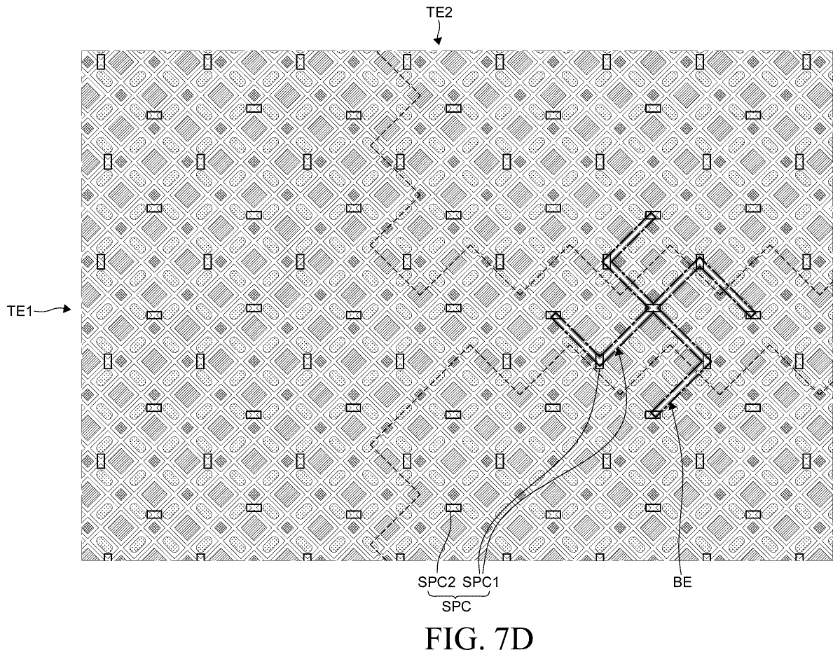

FIGS. 7A to 7D are plan views illustrating shapes of a plurality of bridge electrodes according to another exemplary embodiment of the present disclosure. The configurations of FIGS. 7A to 7D are substantially the same as those of FIGS. 1 to 6C except shapes of a plurality of first spacers SPC1. Therefore, for convenience of description, a redundant description other than the plurality of first spacers SPC1 will be omitted or briefly given.

As one example, the adjacent first spacers SPC1 may be connected to each other to have a closed curve shape, and plurality of bridge electrodes BE may have the same shape as the first spacer on a plane. Referring to FIGS. 7A to 7D, a plurality of first spacers SPC1 may be disposed to connect a plurality of adjacent second touch electrodes TE2. Further, adjacent first spacers SPC1 may be connected to each other. In this case, the first spacer SPC1 may have an open curve shape in which at least one surface is open. The plurality of bridge electrodes BE may have the same shape as the plurality of first spacers SPC1 on a plane. For example, the plurality of bridge electrodes BE and the plurality of first spacers SPC1 may have an open curve shape in which at least one surface is open, but is not limited thereto. Accordingly, the area of the plurality of bridge electrodes BE is increased, so that a resistance that may be used as the bridge electrode BE of the display device 100 may be obtained.

The shapes of the plurality of first spacers SPC1 and the plurality of bridge electrodes BE may not be limited as long as they connect the plurality of second touch electrodes TE2 and form an open curve with one surface open.

For example, when the plurality of first spacers and the plurality of bridge electrodes have a closed curve shape on a plane, the second electrode disposed inside the closed curve shape may be electrically disconnected from the second electrode disposed outside the closed curve shape.

In the display device 200 according to another exemplary embodiment of the present disclosure, the plurality of first spacers SPC1 and the plurality of bridge electrodes BE have an open curve shape in which at least one surface is open on a plane. Therefore, the second electrode 123 which does not overlap the open curve inside the open curve shape may be electrically connected to the second electrode 123 which does not overlap the open curve outside the open curve shape. Accordingly, the luminous efficiency of the display device 200 may be improved.

In the display device 200 according to another exemplary embodiment of the present disclosure, the plurality of auxiliary electrodes AE and the plurality of bridge electrodes BE are formed by the same process and the same material to reduce the mask and reduce the process time and process cost.

Further, in the display device 200 according to another exemplary embodiment of the present disclosure, the plurality of bridge electrodes BE is disposed on the first spacer SPC1 so that a part of a layer included in the display device may be integrated. For example, the organic insulating layer 118 may planarize the lower portion instead of the generally used organic encapsulation layer. Further, the organic insulating layer 118 serves as an insulating layer between the bridge electrode BE and the plurality of touch electrodes TE to exclude the touch interlayer insulating layer. Accordingly, in the display device 200 according to another exemplary embodiment of the present disclosure, the stacking thickness is reduced to maximize flexibility.

Further, in the display device 200 according to another exemplary embodiment of the present disclosure, the plurality of first spacers SPC1 and the plurality of bridge electrodes BE have an open curve shape in which at least one surface is open on a plane, and the second electrode 123, which does not overlap the open curve inside or outside the open curve shape, may be electrically connected to each other. Accordingly, the luminous efficiency of the display device 200 may be improved.

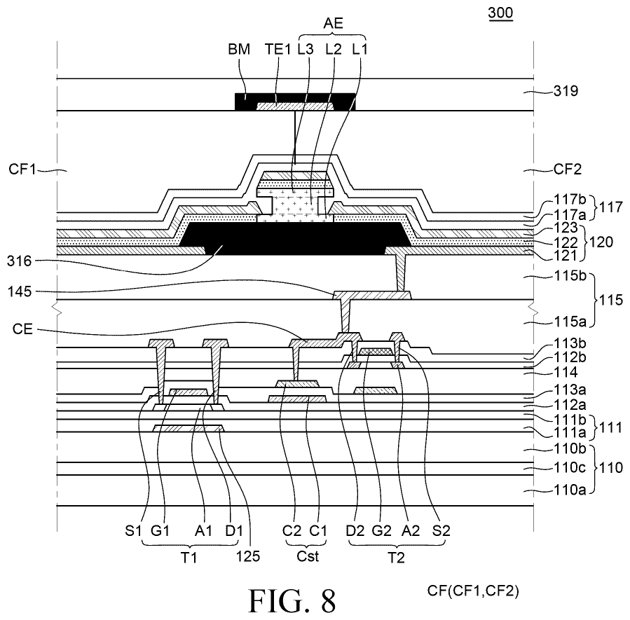

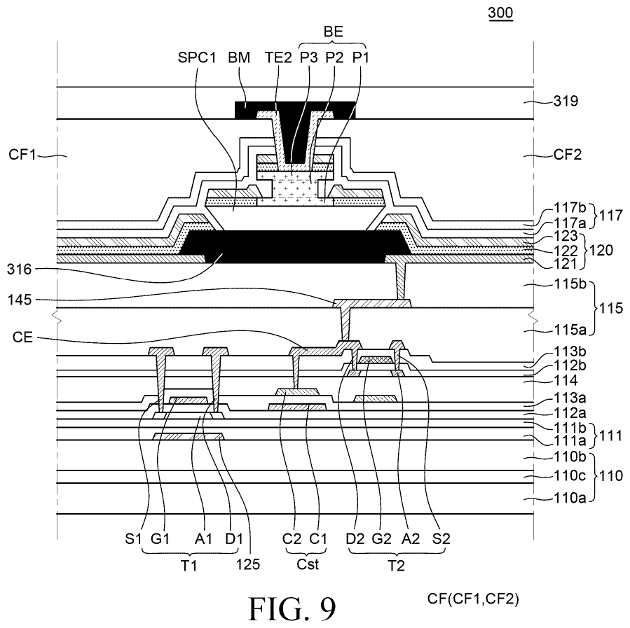

FIG. 8 is a cross-sectional view of a display device according to still another exemplary embodiment of the present disclosure. FIG. 9 is a cross-sectional view of a display device according to still another exemplary embodiment of the present disclosure. The display device 300 of FIGS. 8 and 9 has the substantially same configuration as the display device 100 of FIGS. 1 to 6C or the display device 200 of FIGS. 7A to 7D except for the bank 316, the color filter CF, and the black matrix BM. Therefore, for convenience of description, a redundant description excluding the bank 316, the color filter CF, and the black matrix BM will be omitted or briefly given.

Referring to FIGS. 8 and 9, a display device 300 according to still another exemplary embodiment of the present disclosure may further include a color filter CF which is disposed to cover the encapsulation unit 117 and planarizes an upper portion of the encapsulation unit 117.

For example, the color filter CF may be formed in each of the plurality of sub-pixels SP and may be configured to have a wavelength that transmits light of a specific wavelength.

A touch sensing unit including a plurality of touch electrodes TE and a plurality of bridge electrodes BE may be disposed on the color filter CF.

The plurality of touch electrodes TE may include a plurality of first touch electrodes TE1 extending in a first direction and electrically connected to each other, and a plurality of second touch electrodes TE2 extending in a second direction intersecting the first direction. The plurality of second touch electrodes TE2 disposed adjacent to each other may be electrically connected by the plurality of bridge electrodes BE.

For example, the plurality of first touch electrodes TE1 and the plurality of second touch electrodes TE2 may be disposed on the same layer, but is not limited thereto. However, in an area where the plurality of first touch electrodes TE1 and the plurality of second touch electrodes TE2 intersect, the plurality of second touch electrodes TE2 may be disposed to be separated, and the plurality of separated second touch electrodes TE2 may be connected by the bridge electrode BE. A color filter layer CF is disposed between the plurality of bridge electrodes BE and the plurality of touch electrodes TE to insulate the plurality of bridge electrodes BE and the plurality of touch electrodes TE.

For example, when the plurality of touch electrodes TE and the bridge electrode BE are insulated by the color filter layer CF, the occurrence of unnecessary noise is reduced as the conductivity is lowered so that the touch performance may be improved.

The bridge electrode BE may include a first layer P1, a second layer P2 on the first layer P1, and a third layer P3 on the second layer P2. In this case, a width of the second layer P2 may be smaller than a width of the first layer P1 and a width of the third layer P3, but is not limited thereto. For example, a thickness of the second layer P2 may be greater than a width of the first layer P1 and a width of the third layer P3, but is not limited thereto. For example, the bridge electrode BE may have a three-layer structure of titanium (Ti), aluminum (Al), and titanium (Ti), but is not limited thereto.

As the touch sensing unit including the plurality of touch electrodes TE and the plurality of bridge electrodes BE is disposed at the top of the display device 300, the touch performance may be improved.

The display device may further include a black matrix BM disposed on the color filter layer CF so as to cover the plurality of touch electrodes TE and overlapping the bank 316. For example, the black matrix BM may be provided in an integrated mesh shape to correspond to the non-emission areas of the plurality of light emitting elements 120, but is not limited thereto.

The black matrix BM may include a light absorbing material that absorbs a visible light wavelength band. For example, the black matrix BM may be a kind of light blocking member. For example, the black matrix BM may be made of a material that may be processed at a low temperature of about 100° C. or less, preferably about 85° C. or less. When the black matrix BM is made of a material capable of a low-temperature process, thermal damage to the light emitting element 120 due to the formation of the black matrix BM may be minimized.

The protective layer 319 may be disposed to cover the black matrix BM. The protective layer 119 may be formed of an organic insulating layer. For example, the protective layer 319 may be disposed to cover the black matrix BM and a portion of the color filter layer CF exposed by the black matrix BM. The protective layer 319 may protect the components thereunder and planarize an upper portion thereof. Further, the step at the upper layer of the display device 300 is prevented by the protective layer 319 to improve the visibility of the display device 300. For example, the protective layer 319 may include an organic material such as acryl resin, epoxy resin, phenolic resin, polyamide resin, and polyimide resin.

In the display device 300 according to still another exemplary embodiment of the present disclosure, the color filter CF is disposed on the uppermost portion so that the polarization layer generally disposed on the uppermost portion of the display device may be removed.

Further, in the display device 300 according to still another exemplary embodiment of the present disclosure, the bank 316 may be configured as a black bank 316 including an absorbing material. For example, the light absorbing material may include carbon or black ink. The black bank 316 may prevent light emitted from the light emitting element 120 from being directed to the side surface, thereby preventing color mixture between adjacent sub pixels SP and preventing reflection of external light. Accordingly, even if the polarization layer is not disposed, reflectance of the plurality of light emitting elements 120 in the non-emission area may be reduced and light leakage defects may be prevented.

In the display device 300 according to still another exemplary embodiment of the present disclosure, as the plurality of bridge electrodes BE is disposed on the first spacer SPC1, a part of a layer included in the display device may be integrated. For example, except for the generally used organic encapsulation layer, the color filter layer CF may planarize the upper portion instead. Further, the color filter layer CF serves as an insulating layer between the bridge electrode BE and the plurality of touch electrodes TE to exclude the touch interlayer insulating layer. Accordingly, in the display device 300 according to still another exemplary embodiment of the present disclosure, the stacking thickness is reduced to maximize flexibility.

Further, in the display device 300 according to still another exemplary embodiment of the present disclosure, the low-temperature black matrix BM and the black bank 116 are disposed in the non-emission area of the plurality of light emitting elements 120 to suppress light emitted from the plurality of light emitting elements 120 from being directed to the non-emission area of the plurality of light emitting elements 120. Accordingly, even if the polarization layer is not disposed, reflectance in the non-emission area of the plurality of light emitting elements 120 may be reduced, and light leakage defects may be prevented.

The exemplary embodiments of the present disclosure can also be described as follows:

According to an aspect of the present disclosure, a display device includes a substrate on which a plurality of sub pixels is disposed, a plurality of light emitting elements which are disposed in the plurality of sub pixels and includes a first electrode, an organic layer, and a second electrode, a bank which is disposed so as to cover an end of the first electrode, a plurality of auxiliary electrodes disposed on the bank, an encapsulation unit which is disposed so as to cover the plurality of light emitting elements and the plurality of auxiliary electrodes, and a touch sensing unit which is disposed on the encapsulation unit and includes a plurality of touch electrodes and a plurality of bridge electrodes which is electrically connected to the plurality of touch electrodes, the plurality of auxiliary electrodes and the plurality of bridge electrodes are formed of the same material.

According to the exemplary configuration of the present disclosure, the plurality of auxiliary electrodes may be electrically connected to the second electrode.

According to an exemplary embodiment of the present disclosure, each of the plurality of auxiliary electrodes and the plurality of bridge electrodes may include a first layer, a second layer on the first layer, and a third layer on the second layer, and a width of the second layer may be smaller than a width of the first layer and a width of the third layer.

According to an exemplary embodiment of the present disclosure, the plurality of touch electrodes may include a plurality of first touch electrodes extending in a first direction and electrically connected to each other, and a plurality of second touch electrodes extending in a second direction intersecting the first direction, and the plurality of second touch electrodes disposed adjacent to each other may be electrically connected by the plurality of bridge electrodes

According to an exemplary embodiment of the present disclosure, the display device may further include a plurality of spacers disposed on the bank, and the plurality of spacers may include a first spacer disposed between the plurality of second touch electrodes and overlapping the bridge electrode, and a second spacer spaced apart from the first spacer.

According to the exemplary embodiment of the present disclosure, the plurality of spacers may have a shape in which a width of an upper surface is wider than a width of a lower surface.

According to the exemplary embodiment of the present disclosure, in an area overlapping the first spacers, the second electrode may be electrically disconnected from the bridge electrode.

According to the exemplary embodiment of the present disclosure, the second electrode may be separated from the side surfaces of the plurality of first spacers.

According to an exemplary embodiment of the present disclosure, adjacent first spacers may be connected to each other to have a closed curve shape, and the plurality of bridge electrodes may have the same shape as the first spacer on a plane.

According to an exemplary embodiment of the present disclosure, the second electrode disposed inside the closed curve shape may be electrically disconnected from the second electrode disposed outside the closed curve shape.

According to an exemplary embodiment of the present disclosure, adjacent first spacers may be connected to each other, the first spacer may have an open curved shape with at least one surface thereof open, and the plurality of bridge electrodes may have the same shape as the first spacer on a plane.

According to the exemplary embodiment of the present disclosure, the encapsulation unit may include a first inorganic encapsulation layer and a second inorganic encapsulation layer on the first inorganic encapsulation layer, and the encapsulation unit may be disposed to cover an upper surface of the second electrode.

According to an exemplary embodiment of the present disclosure, the display device may further include a color filter layer which is disposed to cover the encapsulation unit and planarizes an upper portion of the encapsulation unit, and a black matrix which is disposed on the color filter to cover the plurality of touch electrodes and is disposed to overlap the bank.

According to an exemplary embodiment of the present disclosure, the plurality of first touch electrodes and the plurality of second touch electrodes may be insulated from each other on the same layer.

According to an exemplary embodiment of the present disclosure, the first spacer may be disposed to overlap an area where the plurality of first touch electrodes and the plurality of second touch electrodes intersect.

According to an exemplary embodiment of the present disclosure, the display device may further comprise an organic insulating layer disposed between the plurality of touch electrodes and the plurality of bridge electrodes to insulate the plurality of touch electrodes and the plurality of bridge electrodes.

According to another aspect of the present disclosure, a display device includes a substrate on which a plurality of sub pixels is disposed, a plurality of light emitting elements which are disposed in the plurality of sub pixels and includes a first electrode, an organic layer, and a second electrode, a bank which is disposed so as to cover an end of the first electrode, a plurality of auxiliary electrodes disposed on the bank, an encapsulation unit which is disposed so as to cover the plurality of light emitting elements and the plurality of auxiliary electrode, and a touch sensing unit which is disposed on the encapsulation unit and includes a plurality of touch electrodes and a plurality of bridge electrodes, the plurality of touch electrodes includes a plurality of first touch electrodes which extends in a first direction and is electrically connected to each other and a plurality of second touch electrodes which extends in a second direction intersecting the first direction, the bridge electrode is made of the same material as the plurality of auxiliary electrodes and electrically connects the plurality of second touch electrodes disposed adjacent to each other, and the plurality of bridge electrodes are disposed on the bank between the plurality of second touch electrodes.

According to another exemplary embodiment of the present disclosure, the plurality of auxiliary electrodes may be electrically connected to the second electrode.

According to another exemplary embodiment of the present disclosure, the plurality of auxiliary electrodes and the plurality of bridge electrodes may each include a first layer, a second layer on the first layer, and a third layer on the second layer, and a width of the second layer may be smaller than a width of the first layer and a width of the third layer.

According to another exemplary embodiment of the present disclosure, the display device may further include a plurality of spacers disposed on the bank, the plurality of spacers may include a first spacer disposed between the plurality of second touch electrodes and overlapping the bridge electrode, and a second spacer spaced apart from the first spacer, and the bridge electrode may be disposed on the first spacer.

According to another exemplary embodiment of the present disclosure, the plurality of spacers may have a shape in which the width of the upper surface is wider than the width of the lower surface.

According to another exemplary embodiment of the present disclosure, adjacent first spacers may be connected to each other to have a closed curve shape, and the bridge electrode may have the same shape as the first spacer on a plane.

According to another exemplary embodiment of the present disclosure, adjacent first spacers may be connected to each other, the first spacer may have an open curve shape in which at least one surface is open, and the plurality of bridge electrodes may have the same shape as the first spacer on a plane.

According to another exemplary embodiment of the present disclosure, the encapsulation unit may include a first inorganic encapsulation layer and a second inorganic encapsulation layer on the first inorganic encapsulation layer, and the encapsulation unit may be disposed to cover an upper surface of the second electrode.

According to another exemplary embodiment of the present disclosure, the display device may further include a color filter layer which is disposed to cover the encapsulation unit and planarizes an upper portion of the encapsulation unit, and a black matrix which is disposed to cover the plurality of touch electrodes on the color filter layer and is disposed to overlap the bank.

According to an aspect of the present disclosure, a display device includes a substrate on which a plurality of sub pixels is disposed, a plurality of light emitting elements which are disposed in the plurality of sub pixels and includes a first electrode, an organic layer, and a second electrode, a bank which is disposed so as to cover an end of the first electrode, a plurality of auxiliary electrodes disposed on the bank and electrically connected to the second electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate on which a plurality of sub pixels is disposed;
a plurality of light emitting elements which are disposed in the plurality of sub pixels and includes a first electrode, an organic layer, and a second electrode;
a bank which is disposed so as to cover an end of the first electrode;
a plurality of auxiliary electrodes disposed on the bank;
an encapsulation unit which is disposed so as to cover the plurality of light emitting elements and the plurality of auxiliary electrodes; and
a touch sensing unit which is disposed on the encapsulation unit and includes a plurality of touch electrodes and a plurality of bridge electrodes which is electrically connected to the plurality of touch electrodes,
wherein the plurality of auxiliary electrodes and the plurality of bridge electrodes are formed of the same material.

2. The display device according to claim 1, wherein the plurality of auxiliary electrodes is electrically connected to the second electrode.

3. The display device according to claim 1, wherein each of the plurality of auxiliary electrodes and the plurality of bridge electrodes includes a first layer, a second layer on the first layer, and a third layer on the second layer, and
wherein a width of the second layer is smaller than a width of the first layer and a width of the third layer.

4. The display device according to claim 3, wherein the plurality of touch electrodes includes:
a plurality of first touch electrodes extending in a first direction and electrically connected to each other; and
a plurality of second touch electrodes extending in a second direction intersecting the first direction, and
the plurality of second touch electrodes disposed adjacent to each other is electrically connected by the plurality of bridge electrodes.

5. The display device according to claim 4, further comprising:
a plurality of spacers disposed on the bank, and
wherein the plurality of spacers includes:
a first spacer disposed between the plurality of second touch electrodes and overlapping at least one of the plurality of bridge electrodes; and
a second spacer spaced apart from the first spacer.

6. The display device according to claim 5, wherein the plurality of spacers have a shape in which the width of the upper surface is wider than the width of the lower surface.

7. The display device according to claim 6, wherein first spacers of the plurality of spacers are separated from side surfaces of the second electrode.

8. The display device according to claim 7, wherein first spacers of the plurality of spacers that are adjacent to each other are connected to have a closed curve shape, and
wherein the plurality of bridge electrodes have the same shape as the first spacers on a plane.

9. The display device according to claim 7, wherein first spacers of the plurality of spacers that are adjacent to each other are connected to each other,
wherein the first spacers have an open curved shape with at least one surface thereof open, and wherein the plurality of bridge electrodes have the same shape as the first spacers on a plane.

10. The display device according to claim 7, wherein the encapsulation unit includes a first inorganic encapsulation layer and a second inorganic encapsulation layer on the first inorganic encapsulation layer, and
wherein the encapsulation unit is disposed to cover an upper surface of the second electrode.

11. The display device of claim 10 further comprising:
a color filter layer which is disposed so as to cover the encapsulation unit and planarizes an upper portion of the encapsulation unit; and
a black matrix which is disposed on the color filter layer so as to cover the plurality of touch electrodes and is disposed so as to overlap the bank.

12. A display device comprising:
a substrate on which a plurality of sub pixels is disposed;
a plurality of light emitting elements which are disposed in the plurality of sub pixels and includes a first electrode, an organic layer, and a second electrode;
a bank which is disposed so as to cover an end of the first electrode;
a plurality of auxiliary electrodes disposed on the bank;
an encapsulation unit which is disposed so as to cover the plurality of light emitting elements and the plurality of auxiliary electrodes; and
a touch sensing unit which is disposed on the encapsulation unit and includes a plurality of touch electrodes and a plurality of bridge electrodes,
wherein the plurality of touch electrodes includes a plurality of first touch electrodes which extends in a first direction and is electrically connected to each other and a plurality of second touch electrodes which extends in a second direction intersecting the first direction,
wherein the plurality of bridge electrodes is made of a same material as the plurality of auxiliary electrodes and electrically connects the plurality of second touch electrodes disposed adjacent to each other, and
wherein the plurality of bridge electrodes are disposed on the bank between the plurality of second touch electrodes.

13. The display device according to claim 12, wherein the plurality of auxiliary electrodes is electrically connected to the second electrode.

14. The display device of claim 12, wherein the plurality of auxiliary electrodes and the plurality of bridge electrodes each include a first layer, a second layer on the first layer, and a third layer on the second layer, and
wherein a width of the second layer is smaller than a width of the first layer and a width of the third layer.

15. The display device according to claim 14, further comprising:
a plurality of spacers disposed on the bank,
wherein the plurality of spacers includes:
a first spacer disposed between the plurality of second touch electrodes and overlapping at least one of the plurality of bridge electrodes; and
a second spacer spaced apart from the first spacer, and
wherein the plurality of bridge electrodes is disposed on the first spacer.

16. The display device according to claim 15, wherein the plurality of spacers have a shape in which the width of the upper surface is wider than the width of the lower surface.

17. The display device according to claim 15, wherein first spacers of the plurality of spacers that are adjacent to each other are connected to have a closed curve shape, and
wherein the plurality of bridge electrodes has the same shape as the first spacers on a plane.

18. The display device according to claim 15, wherein first spacers of the plurality of spacers that are adjacent to each other are connected to each other,
wherein the first spacers have an open curved shape with at least one surface thereof open, and wherein the plurality of bridge electrodes have a same shape as the first spacers on a plane.

19. The display device according to claim 15, wherein the encapsulation unit includes a first inorganic encapsulation layer and a second inorganic encapsulation layer on the first inorganic encapsulation layer, and
wherein the encapsulation unit is disposed to cover an upper surface of the second electrode.

20. The display device of claim 19, further comprising:
a color filter layer disposed to cover the encapsulation unit and planarize an upper portion of the encapsulation unit; and
a black matrix disposed to cover the plurality of touch electrodes on the color filter layer and disposed to overlap the bank.
